(19) United States
(12) Patent Application Publication
(10) Pub. No.: US 2011/0298066 A1
(43) Pub. Date: Dec. 8, 2011

(54) MICRO STRUCTURE, MICRO ELECTRO MECHANICAL SYSTEM THEREWITH, AND MANUFACTURING METHOD THEREOF

(75) Inventors: Jong-wan KIM, Changwon-city (KR); Seung-min CHO, Changwon-city (KR)

(73) Assignee: SAMSUNG TECHWIN CO., LTD., Changwon-city (KR)

(21) Appl. No.: 13/152,969

(22) Filed: Jun. 3, 2011

(30) Foreign Application Priority Data
Jun. 4, 2010 (KR) 10-2010-0053028

(51) Int. Cl. H01L 29/84; H01L 21/62

(52) U.S. Cl. 257/418; 438/52; 257/E29.324; 257/E21.52

(57) ABSTRACT

A micro structure includes a base member; a supporting unit disposed on a surface of the base member; a graphene unit which covers at least a portion of the supporting unit and at least a portion of an empty space adjacent to the supporting unit; and a structure unit disposed on at least a portion of the graphene unit over the supporting unit.

### CROSS-REFERENCE TO RELATED PATENT APPLICATION

This application claims the benefit of Korean Patent Application No. 10-2010-0053028, filed on Jun. 4, 2010, in the Korean Intellectual Property Office, the disclosure of which is incorporated herein in its entirety by reference.

### BACKGROUND

1. Field

Apparatuses and methods consistent with exemplary embodiments relate to a micro structure, and more particularly, to a micro structure manufactured by integrating mechanical parts, sensors, actuators, or electrical circuits on a substrate by using micro-technology, a micro electro mechanical system having the micro structure, and a method of manufacturing the same.

2. Description of the Related Art

The term micro electro-mechanical system (MEMS) refers to micro technology used to manufacture an apparatus in which mechanical parts, sensors, actuators, or electrical circuits are integrated on a substrate or to the manufacture of a micro structure by processing silicon, quartz, glass, or metals.

In sensors and actuators that are manufactured by using the MEMS technology, in order to manufacture a driving unit, a diaphragm structure that includes a bridge or a cantilever is manufactured, or a cavity structure is manufactured, and after manufacturing the cavity structure, the cavity structure is protected to prevent impurities penetrating, or the sensors and actuators are maintained in a vacuum state.

For example, a pressure detecting portion of a pressure sensor, a driving unit of an acceleration sensor, a driving unit of an angular accelerator (gyro), a driving unit of a micro motor, or a sensing unit of a sensor that requires heating, such as a gas sensor, can be manufactured by using MEMS technology. Also, wafer lever packages (WLPs) that use a cavity can be manufactured using MEMS technology.

In some cases, a diaphragm structure that includes a bridge or a cantilever or a cavity structure may be used according to the type of MEMS device or may be used to aid operation of the MEMS device.

The diaphragm structure and the cavity structure may be manufactured using surface micro-machining technology or bulk micro-machining technology.

### SUMMARY

Exemplary embodiments may provide a micro structure that can be manufactured in various shapes without having to form a sacrifice layer, a MEMS that includes the micro structure, and a method of manufacturing the micro structure.

According to an aspect of an exemplary embodiment, there is provided a micro structure comprising: a base member; a supporting unit disposed on a surface of the base member; a graphene unit which covers at least a portion of the supporting unit and at least a portion of an empty space adjacent to the supporting unit; and a structure unit on at least a portion of the graphene unit over the supporting unit.

The supporting unit may have a patterned structure.

The supporting unit may have a hollow through structure.

The supporting unit may include at least a first supporting unit and a second supporting unit, and the structure unit may form a bridge spanning the first supporting unit and the second supporting unit.

The structure unit may include a cantilever, wherein a first end of the structure unit is supported by the supporting unit and a second end of the structure unit extends above the empty space.

The micro structure may further include an insulating unit disposed between the graphene unit and the structure unit.

The structure unit may include a first structure layer disposed on at least the portion of the graphene unit over the supporting unit, and a second structure layer disposed on the first structure layer.

The second structure layer may include: a first electrode terminal and a second electrode terminal; a first connection wire extending from the first electrode terminal and a second connection wire extending from the second electrode terminal; and a piezo resistor connected between the first connection wire and the second connection wire.

According to an aspect of another exemplary embodiment, there is provided a micro electro-machining system that comprises the micro structure.

According to an aspect of another exemplary embodiment, there is provided a method of manufacturing a micro structure, the method including: forming a supporting layer on a surface of a base member; forming a supporting pattern by patterning the supporting layer; forming a graphene layer which covers to cover at least a portion of the supporting pattern; forming a structure layer on at least a portion of the graphene layer over the supporting pattern; and forming a structure unit by patterning the structure layer.

Supporting units may be formed by etching at least a portion of the supporting pattern.

Supporting units may be formed by etching at least a portion of the structure layer, the graphene layer, and the supporting pattern.

The graphene layer may be formed covering the entire supporting layer.

The graphene layer may be formed covering a first portion of the supporting pattern and exposing a second portion of the supporting pattern.

The graphene layer may be formed by transferring graphene onto at least the portion of the supporting pattern.

The graphene unit may be formed by patterning the graphene layer.

The structure layer may be formed by a semiconductor thin film deposition process.

The method may further include forming an insulating layer between the graphene layer and the structure layer.

### BRIEF DESCRIPTION OF THE DRAWINGS

The above and/or other aspects will become more apparent by describing in detail exemplary embodiments with reference to the attached drawings in which:

FIGS. 1 and 2 are schematic cross-sectional views of a micro structure according to a comparative example;

FIG. 3 is a schematic cross-sectional view of a micro structure according to an exemplary embodiment;

FIG. 4 is a photograph of a micro structure that includes a bridge and a cantilever on a supporting unit according to another exemplary embodiment;

FIG. 5 is a schematic perspective view of a micro pressure sensor that uses a piezo resistor as an exemplary embodiment of a micro electro-mechanical system (MEMS) that includes a micro structure; and

FIGS. 6 through 10 are cross-sectional views illustrating a method of manufacturing a micro structure according to another exemplary embodiment.

### DETAILED DESCRIPTION

Exemplary embodiments will now be described more fully with reference to the accompanying drawings.

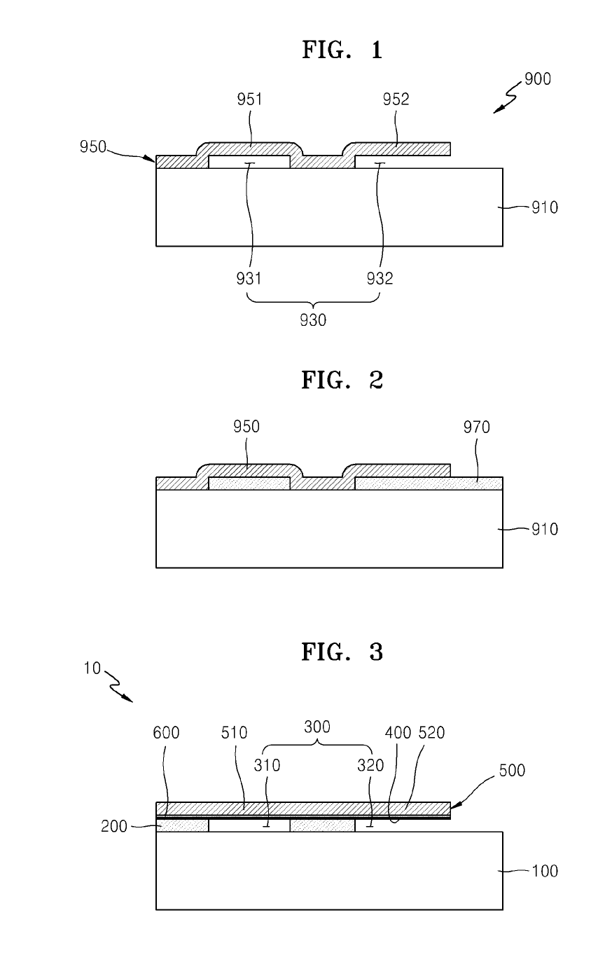

FIG. 1 is a schematic cross-sectional view of a micro structure 900 according to a comparative example. FIG. 2 is a schematic cross-sectional view of the micro structure 900, in which a sacrifice layer 970 is formed under a structure unit 950 to form an empty space 930 of FIG. 1.

Referring to FIGS. 1 and 2, in the micro structure 900, the structure unit 950 is formed on a base member 910. In order to form a sensor and an actuator by using MEMS technology, a driving unit is formed in the micro structure 900.

The driving unit may be formed to have a diaphragm structure or a cavity structure that includes the empty space 930. At this point, the driving unit may include the structure unit 950 that includes a bridge 951 and/or a cantilever 952 having the empty space 930 thereunder. The empty space 930 under the driving unit may include a bridge empty space 931 and a cantilever empty space 932 respectively formed under the bridge 951 and/or the cantilever 952.

Surface micro-machining technology may be used to manufacture a diaphragm structure or a cavity structure. In this case, a sacrifice layer 970 for forming the empty space 930 is used under the structure unit 950. The sacrifice layer 970 is formed on the base member 910, and afterwards, a patterning of the sacrifice layer 970 is performed and the structure unit 950 is formed on the patterned sacrifice layer 970.

In order to form the structure unit 950 having a diaphragm structure or a cavity structure, the sacrifice layer 970 may be selectively etched while maintaining the shape of the structure unit 950. Selective etching of the sacrifice layer 970 may be performed by using a wet etching method or a dry etching method.

In the case of wet etching, the material for forming the sacrifice layer 970 may be limited to materials that have an etch selectivity with respect to the material used to form the structure unit 950. Also, in the case of wet etching, manufacturing a micro structure is difficult due to the difficulty of removing an etching solution and washing.

A dry etching method may be an isotropic etching method or an anisotropic etching method. In order to etch the sacrifice layer 970, a space that is not covered by the structure unit 950 is needed. In order to perform uniform etching, holes for passing an etching-gas may be formed in the structure unit 950, and the sacrifice layer 970 may be etched by passing the etching-gas through the holes.

Accordingly, in the case of dry etching, the shape of the structure unit 950 is limited and the process may be complicated since a subsequent process for filling the holes may be required after etching.

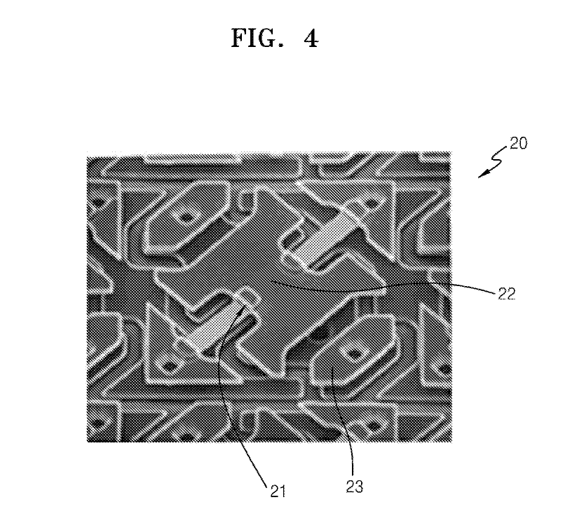

FIG. 3 is a schematic cross-sectional view of a micro structure 10 according to an exemplary embodiment.

Referring to FIG. 3, the micro structure 10 may include a base member 100, supporting units 200, a graphene unit 400, and a structure unit 500.

The base member 100 supports the rest of the micro structure 10. The supporting units 200 are disposed at least on one side of the base member 100 together with an empty space 300. The graphene unit 400 is disposed to cover at least portions of the supporting units 200 and the empty space 300. The structure unit 500 is disposed on at least portions of the graphene unit 400 and the supporting units 200.

The graphene unit 400 is formed of graphene and covers at least portions of the supporting units 200 and the empty space 300. The graphene is a substantially two-dimensional material that has almost no thickness. Therefore, the empty space 300 may be readily secured under the structure unit 500 by forming the structure unit 500 after forming the graphene above the empty space 300.

That is, the micro structure 10 may be formed without having to form the sacrifice layer 970 (refer to FIG. 2). Accordingly, the process of etching the sacrifice layer 970 is unnecessary. As a result, the micro structure 10 may be formed by using a simple process.

Also, since the graphene unit 400 has a substantially two dimensional shape with little thickness, the graphene unit 400, for securing the empty space 300 below the structure unit 500, has little effect on the structure of the micro structure 10. Also, since the graphene of the graphene unit 400 is transparent, an alignment process may be easily performed.

In order to form a sensor and an actuator by using MEMS technology, a driving unit is formed in the micro structure 10. The driving unit may be formed to have a diaphragm structure or a cavity structure that includes the empty space 300 below the driving unit.

The driving unit may be the structure unit 500 formed on the supporting units 200 and the empty space 300. The structure unit 500 may include a bridge 510 and/or a cantilever 520. The bridge 510 may cover the supporting units 200 having the empty space 300 is disposed therebetween. An end of the cantilever 520 may be supported by the supporting unit 200 and the other end may extend above the empty space 300.

The empty space 300 provides a space in which the structure unit 500 can be driven, and may include a bridge space 310 and a cantilever space 320. The bridge space 310 is a space between the supporting units 200 over which the bridge 510 may be formed. The cantilever space 320 is a space over which the cantilever 520 may be formed and is under the structure unit 500.

The supporting unit 200 may have a hollow through structure or a patterned structure. The graphene unit 400 may be formed by transferring graphene onto the supporting unit 200. The structure of the supporting unit 200 and a forming method of the graphene unit 400 according to the current embodiment are not limited. The graphene unit 400 may be formed by any method by which thin graphene may be formed on the supporting unit 200 and then the empty space 300 can be formed between the supporting units 200.

Here, the graphene unit 400 may be formed of graphene to cover at least a portion of the supporting unit 200 and the empty space 300. In the micro structure 10, the graphene unit 400 may be formed to cover the entire supporting unit 200. In the micro structure 10 according to another exemplary embodiment, the graphene unit 400 may be formed on the supporting unit 200 while exposing a portion of the supporting unit 200.

The base member 100 may be formed of a polymer material such as polyimide. The base member 100 according to the current embodiment may be formed of at least one of polyimide, polyethylene terephthalate (PET), FR-4, and polydimethylsiloxane (PDMS).

The graphene unit 400 is a substantially two dimensional carbon structure and is formed of a graphite material. Electrons in the graphene unit 400 behave as relativistic particles having no rest mass, and have the characteristic of moving at a velocity of approximately 1 million meters per second. Although this velocity is 300 times slower than light in a vacuum state, it is still much faster than the velocity of electrons in a conductor or a semiconductor.

Accordingly, graphene that is used to form the graphene unit 400 has high electrical conductivity. However, according to one or more exemplary embodiments, for example, when the structure unit 500 is required to have electrical conductivity, the graphene unit 400 is electrically insulated from the structure unit 500. In this case, the micro structure 10 may further include an insulating unit 600, having an electrical insulation property, between the graphene unit 400 and the structure unit 500.

According to the current embodiment, the structure unit 500 that can be a driving unit for manufacturing a sensor and an actuator of a MEMS may be manufactured to have various shapes by using a simple process without having to form a sacrifice layer. Accordingly, the micro structure 10 can be manufactured to have various shapes by performing a simple process.

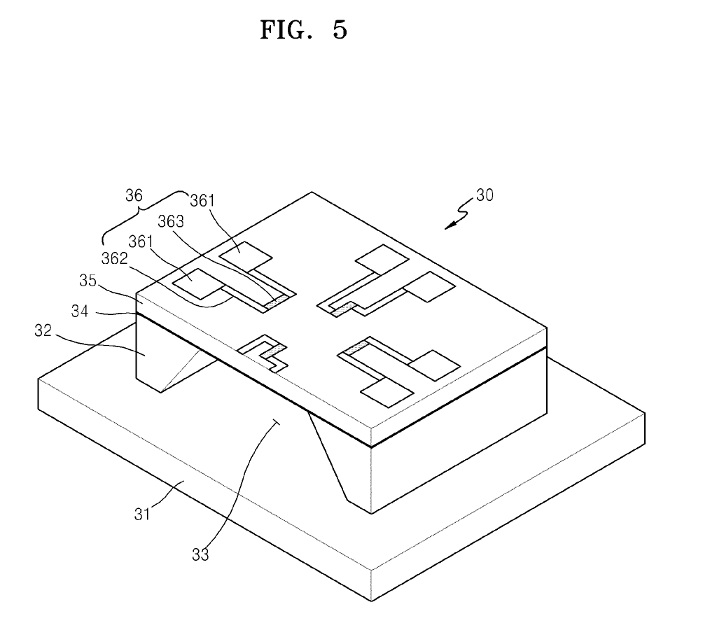

FIG. 4 is a photograph of a micro structure 20 according to another exemplary embodiment. Referring to FIG. 4, the micro structure 20 includes a bridge 22 and/or a cantilever 23 on a supporting unit 21. The supporting unit 21, the bridge 22, and the cantilever 23 of FIG. 4 respectively correspond to the supporting unit 200, the bridge 510, and the cantilever 520 of FIG. 3.

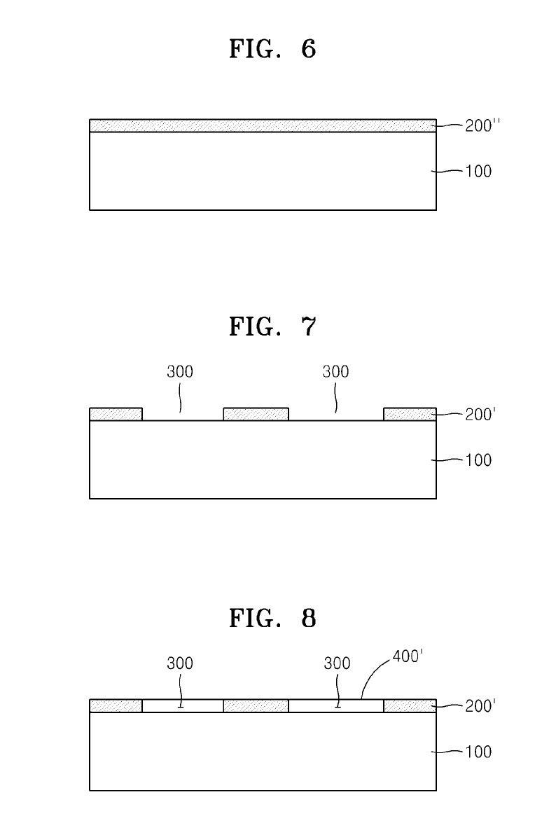

The structure unit 500 may be formed as a structure having at least two layers. An example of the structure unit 500 is depicted in FIG. 5. In this case, each of the layers may be graphene layers. Alternately, the structure unit 500 may have a double layer structure that includes graphene layers.

In this case, a micro pressure sensor 30 (refer to FIG. 5) may include a first structure layer 35 and a second structure layer 36. The first structure layer 35 may be disposed at least on a portion of a graphene unit 34 and a supporting unit 32. The second structure layer 36 may be disposed on the first structure layer 35.

FIG. 5 is a schematic perspective view of a micro pressure sensor 30 that uses a piezo resistor as a practical exemplary embodiment of a MEMS that includes the micro structure 10 of FIG. 3.

Referring to FIG. 5, the micro pressure sensor 30 includes a base member 31, a supporting unit 32, the graphene unit 34, the first structure layer 35, and the second structure layer 36.

The base member 31 supports the rest of the micro pressure sensor 30. The supporting unit 32 is disposed at least on one surface of the base member 31 together with an empty space 33. the supporting unit 32 may include silicon material. The graphene unit 34 may cover at least a portion of the supporting unit 32 and the empty space 33.

The first structure layer 35 may be disposed at least on a portion of the graphene unit 34 and the supporting unit 32. The second structure layer 36 may be disposed on the first structure layer 35. The first structure layer 35 may be a membrane type.

The second structure layer 36 may include a pair of electrode terminals 361, connection wires 362, and a piezo resistor 363. The pair of electrode terminals 361 may be terminals to be electrically connected to an external device. The connection wires 362 may extend from the electrode terminals 361. The piezo resistor 363 includes a piezoelectric material and may be connected between the connection wires 362.

In this case, when a pressure is applied to the first structure layer 35, the piezo resistor 363 may be deformed, and as a result, resistance values measured at the pair of electrode terminals 361 may vary. In this case, the pressure applied to the first structure layer 35 may be measured according to the resistance values measured at the pair of electrode terminals 361.

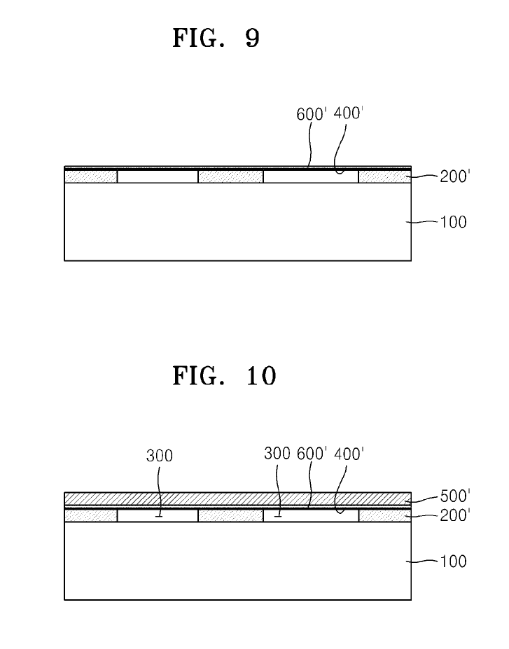

FIGS. 6 through 10 are cross-sectional views illustrating steps of manufacturing the micro structure 10 according to an exemplary embodiment. FIGS. 6 through 10 illustrate a method of manufacturing the micro structure 10 of FIG. 3, and thus, the descriptions of the micro structure 10 of FIGS. 3 through 5 will not be repeated.

Referring to FIGS. 6 through 10, the method of manufacturing the micro structure 10 includes: forming a supporting layer; forming a supporting pattern; forming a graphene layer; forming a structure layer; and forming a structure unit.

The forming of the supporting layer (FIG. 6) may include forming a supporting layer 200″ at least on one surface of the base member 100. The forming of the supporting pattern (FIG. 7) may include forming a supporting pattern 200′ to have a predetermined pattern by patterning the supporting layer 200″ to form the empty space 300. The forming of the graphene layer (FIG. 8) may include forming a graphene layer 400′ by using graphene at least on a portion of the supporting pattern 200′ and the empty space 300.

The forming of the graphene layer (FIG. 8) may include forming the graphene layer 400′ to cover the entire supporting pattern 200′. According to an aspect of another exemplary embodiment, the forming of the graphene layer (FIG. 8) may include forming the graphene layer 400′ to cover the entire supporting pattern 200′ or to expose a portion of the supporting pattern 200′. The graphene layer 400′ may be formed by transferring graphene onto the supporting pattern 200′. However, alternately, in the method of manufacturing the micro structure 10 according to the current embodiment, the graphene layer 400′ may be formed by using another method, and thus, the method of forming the graphene layer 400′ is not limited.

The graphene unit 400 may be formed by patterning the graphene layer 400′ to have a predetermined shape. Also, the supporting unit 200 may be formed to have a hollow through structure or a patterned structure. The graphene layer 400′ may be formed by transferring graphene onto the supporting unit 200 having a hollow through structure or a patterned structure. Here, the method of forming the structure of the supporting unit 200 according to the current embodiment is not limited.

In the forming of the structure layer 500′ (FIG. 10), the structure layer 500′ may be formed at least on a portion of the supporting pattern 200′ and the graphene layer 400′ by using a semiconductor thin film deposition process.

In the forming of the structure unit 500 (FIG. 3), the supporting unit 200 that supports the structure unit 500 may be formed by etching at least a portion of the supporting pattern 200′. At this point, in the forming of the structure unit 500 (FIG. 3), the structure unit 500 may be formed by etching at least a portion of the structure layer 500′, the graphene layer 400′, and the supporting pattern 200′. When the structure unit 500 is formed, the graphene unit 400 may also be formed by patterning the graphene layer 400′ to have a predetermined pattern.

Graphene that is used to form the graphene unit 400 may have a high electrical conductivity. However, if desired, the graphene unit 400 may be electrically insulated from the structure unit 500. In this case, an insulating unit 600, having an electrical insulation property, may be formed between the graphene unit 400 and the structure unit 500 in the micro structure 10.

For this purpose, the method of forming the micro structure 10 may further include forming an insulating layer (FIG. 9). The insulating layer 600′ has an electrical insulation property and is formed between the graphene layer 400′ and the structure layer 500′. In this case, when the structure unit 500 is formed (FIG. 3), the insulating unit 600 may be formed together with the structure unit 500 by etching at least a portion of the insulating layer 600′ to have a predetermined pattern.

According to one or more exemplary embodiments, the structure unit 500 that can be a driving unit for manufacturing a sensor and an actuator of a MEMS can be manufactured to have one of various shapes by a simple process using graphene without the need of forming a sacrifice layer. Therefore, the micro structure 10 can be formed to have various shapes by a simple process.

According to one or more exemplary embodiments, a micro structure can be formed to have various shapes without having to form a sacrifice layer.

While exemplary embodiments have been particularly shown and described, it will be understood by those of ordinary skill in the art that various changes in form and details may be made therein without departing from the spirit and scope of the present inventive concept as defined by the following claims.

What is claimed is:

1. A micro structure comprising:
a base member;
a supporting unit disposed on a surface of the base member;
a graphene unit which covers at least a portion of the supporting unit and at least a portion of an empty space adjacent to the supporting unit; and
a structure unit disposed on at least a portion of the graphene unit over the supporting unit.

2. The micro structure of claim 1, wherein the supporting unit has a patterned structure.

3. The micro structure of claim 1, wherein the supporting unit has a hollow through structure.

4. The micro structure of claim 1, wherein the supporting unit comprises at least a first supporting unit and a second supporting unit, and the structure unit comprises a bridge spanning the first supporting unit and the second supporting unit.

5. The micro structure of claim 1, wherein the structure unit comprises a cantilever, wherein a first end of the structure unit is supported by the supporting unit and a second end of the structure unit extends above the empty space.

6. The micro structure of claim 1, further comprises an insulating unit disposed between the graphene unit and the structure unit.

7. The micro structure of claim 1, wherein the structure unit comprises:
a first structure layer disposed on at least the portion of the graphene unit over the supporting unit; and
a second structure layer disposed on the first structure layer.

8. The micro structure of claim 7, wherein the second structure layer comprises:
a first electrode terminal and a second electrode terminal;
a first connection wire extending the first electrode terminal and a second connection wire extending from the second electrode terminal; and
a piezo resistor connected between the first connection wire and the second connection wire.

9. A micro electro-machining system that comprises the micro structure of claim 1.

10. A method of manufacturing a micro structure, the method comprising:
forming a supporting layer on a surface of a base member;
forming a supporting pattern by patterning the supporting layer;
forming a graphene layer which covers at least a portion of the supporting pattern;
forming a structure layer on at least a portion of the graphene layer over the supporting pattern; and
forming a structure unit by patterning the structure layer.

11. The method of claim 10, further comprising forming supporting units by etching at least a portion of the supporting pattern.

12. The method of claim 10, wherein the forming the structure unit comprises etching at least a portion of the structure layer, the graphene layer, and the supporting pattern.

13. The method of claim 10, wherein the forming the graphene layer comprises covering the entire supporting pattern.

14. The method of claim 10, wherein the forming the graphene layer comprises covering a first portion of the supporting pattern and exposing a second portion of the supporting pattern.

15. The method of claim 10, wherein the forming the graphene layer comprises transferring graphene onto at least the portion of the supporting pattern.

16. The method of claim 10, wherein a graphene unit is formed by patterning the graphene layer.

17. The method of claim 16, wherein the forming the structure layer comprises a semiconductor thin film deposition process.

18. The method of claim 10, further comprising forming an insulating layer between the graphene layer and the structure layer.

19. A micro structure comprising:
a base member;
a supporting unit disposed on the base member;
a graphene unit disposed on at least a portion of the supporting unit, wherein the graphene unit extends beyond the supporting unit over an empty space adjacent to the supporting unit;
a structure unit disposed on the graphene unit.

20. A method of manufacturing a micro structure, the method comprising:
forming a supporting unit on a base member;
forming a graphene unit on at least a portion of the supporting unit, wherein the graphene unit extends beyond the supporting unit over an empty space adjacent to the supporting unit;
forming a structure unit on the graphene unit.
